(19) United States
(12) Patent Application Publication
(10) Pub. No.: US 2015/0001631 A1
(43) Pub. Date: Jan. 1, 2015

(54) CMOS TECHNOLOGY INTEGRATION

(71) Applicant: QUALCOMM Incorporated, San Diego, CA (US)

(72) Inventors: Xia LI, San Diego, CA (US); Ming CAI, San Diego, CA (US); Samit SENGUPTA, San Diego, CA (US); PR CHIDAMBARAM, San Diego, CA (US)

(73) Assignee: QUALCOMM Incorporated, San Diego, CA (US)

(21) Appl. No.: 14/109,203

(22) Filed: Dec. 17, 2013

Related U.S. Application Data
(60) Provisional application No. 61/840,686, filed on Jun. 28, 2013.

(51) Int. Cl. H01L 21/8238; H01L 27/092

(52) U.S. Cl. CPC H01L 21/8238; H01L 27/092
USPC 257/369; 438/199

(57) ABSTRACT

Complementary metal oxide semiconductor (CMOS) devices include input/output (I/O) devices and core function devices. A method includes forming first conduction type wells for the I/O devices and the core function devices with a well mask. Such a method also includes creating at least one baseline device of a first conduction type, at least one first threshold voltage device of the first conduction type, and at least one second threshold device of the first conduction type by tuning a conduction type drive current ratio with a threshold voltage mask. The method also includes controlling a gate critical dimension for the first conduction type devices and/or at least one second conduction type device using a gate mask.

### CROSS-REFERENCE TO RELATED APPLICATION

The present application claims the benefit of U.S. Provisional Patent Application No. 61/840,686, filed on Jun. 28, 2013, in the names of X. Li et al., the disclosure of which is expressly incorporated by reference herein in its entirety.

### BACKGROUND

1. Field

Aspects of the present disclosure relate generally to integrated circuits, and more particularly to the integration of high performance, low cost, low power circuitry.

2. Background

Semiconductor integrated circuits are currently used for many logic and other applications in consumer products. Semiconductor device and circuit manufacturing begins with a baseline technology for a semiconductor feature size, e.g., 0.28 nm feature size technologies. These baseline technologies are improved upon by fine-tuning the manufacturing process and/or optimizing circuit designs.

### SUMMARY

In one aspect of the disclosure, a method for fabricating a complementary metal oxide semiconductor (CMOS) device, including input/output (I/O) devices and core function devices, is described. The method includes forming first conduction type wells for the I/O devices and the core function devices with a well mask. The method also includes creating a baseline device of a first conduction type, a first threshold voltage device of the first conduction type and a second threshold device of the first conduction type. These devices may be created by tuning a conduction type drive current ratio with a threshold voltage mask. The method also includes controlling a gate critical dimension of the first conduction type devices and/or a second conduction type device using a gate mask.

In another aspect of the present disclosure, a mask set for making a complementary metal oxide semiconductor (CMOS) device, including input/output (I/O) devices and core function devices, is described. The method includes well mask means for forming first conduction type wells for the I/O devices and the core function devices. Such a mask set also includes threshold voltage mask means for creating at least one baseline device, at least a first threshold voltage device, and at least one second threshold device by tuning a conduction type drive current ratio. The mask set also includes gate mask means for controlling a gate critical dimension for the first conduction type and/or a second conduction type.

A mask set for fabricating a complementary metal oxide semiconductor (CMOS) device including input/output (I/O) devices and core function devices, in accordance with one or more aspects of the present disclosure, includes a well mask that forms first conduction type wells for the I/O devices and the core function devices. Such a mask set also includes a threshold voltage mask that creates at least one baseline device, at least a first threshold voltage device, and at least one second threshold device by tuning a conduction type drive current ratio. The mask set also includes a gate mask that controls a gate critical dimension for the first conduction type and/or a second conduction type.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates a cutaway view of complementary metal-oxide-semiconductor (CMOS) devices in a baseline technology

FIG. 2 illustrates a diagram of a technology improvement flow of the related art.

FIG. 3 illustrates a chart comparing leakage current with maximum frequency for related art technologies.

FIG. 4 illustrates a mask chart for high performance plus devices in the related art.

FIG. 5 illustrates a diagram of a technology improvement flow according to one aspect of the disclosure.

FIG. 6 illustrates a mask count for technology improvement in accordance with an aspect of the present disclosure.

FIG. 7 illustrates a mask chart for high performance plus low cost devices in accordance with an aspect of the present disclosure.

FIG. 8 illustrates a process chart illustrating a process in accordance with an aspect of the present disclosure.

FIG. 9 is a block diagram showing an exemplary wireless communication system in which a configuration of the disclosure may be advantageously employed.

FIG. 10 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

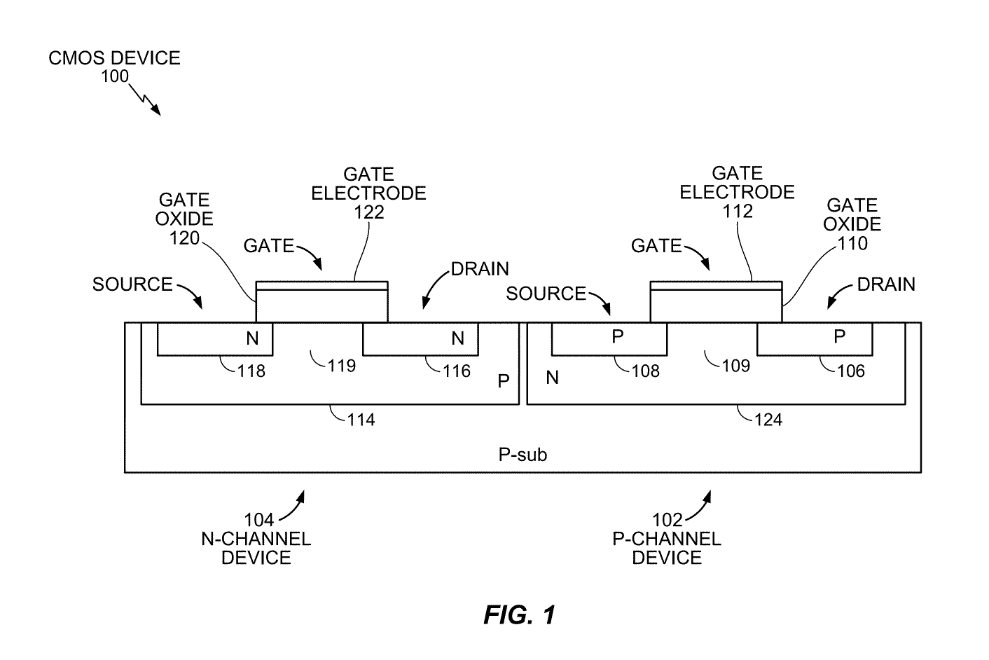

FIG. 1 illustrates a cutaway view of a complementary metal-oxide-semiconductor (CMOS) device 100 in a baseline technology. A CMOS device 100 includes a p-channel device 102 and an n-channel device 104. Within the p-channel device 102, an n-type doped well 124 is created from a p-substrate semiconductor (e.g., silicon). P-type doped regions 106 and 108 are used for the source and drain regions, and a gate oxide (or high-k dielectric) layer 110 having a baseline thickness is grown or otherwise deposited on a surface of the CMOS device. A gate electrode (which may be metal, polysilicon, or other conductive material) 112 is placed on the gate oxide (Gox) 110, creating the gate electrode controlling the electric field, and thus the charge carriers present, in between the p-type doped regions 106 and 108. The space between the p-type doped regions 106 and 108 is called the channel 109. When proper voltages are applied, p-type charge carriers are present in the channel 109 to allow current flow between the source and drain of the p-channel device 102. Such a device is called a p-channel metal-oxide-semiconductor (PMOS) device.

Within the n-channel device 104, a p-type doped well 114 is created from a p-type substrate. N-type doped regions 116 and 118 are used for the source and drain contacts. A gate oxide (or high-k dielectric) layer 120 having a baseline thickness is grown or otherwise deposited on a surface of the CMOS device. A gate electrode (which may be metal, polysilicon, or other conductive material) 122 is placed on the gate oxide layer 120, creating the gate electrode controlling the electric field, and thus the charge carriers present, in between the n-type doped regions 116 and 118. The space between the n-type doped regions 116 and 118 is called the channel 119. When proper voltages are applied, n-type charge carriers are present in the channel 109 to allow current flow between the source and drain of the n-channel device 104. Such a device is called an n-channel metal-oxide-semiconductor (NMOS) device. When both the PMOS devices 102 and the NMOS devices 104 are used within the same circuit or on the same semiconductor substrate (e.g., a p-type doped well 114 or n-type doped well 124 deposited in p type substrate), the devices are considered as “complementary” devices using different channel charge carriers, more commonly known as CMOS.

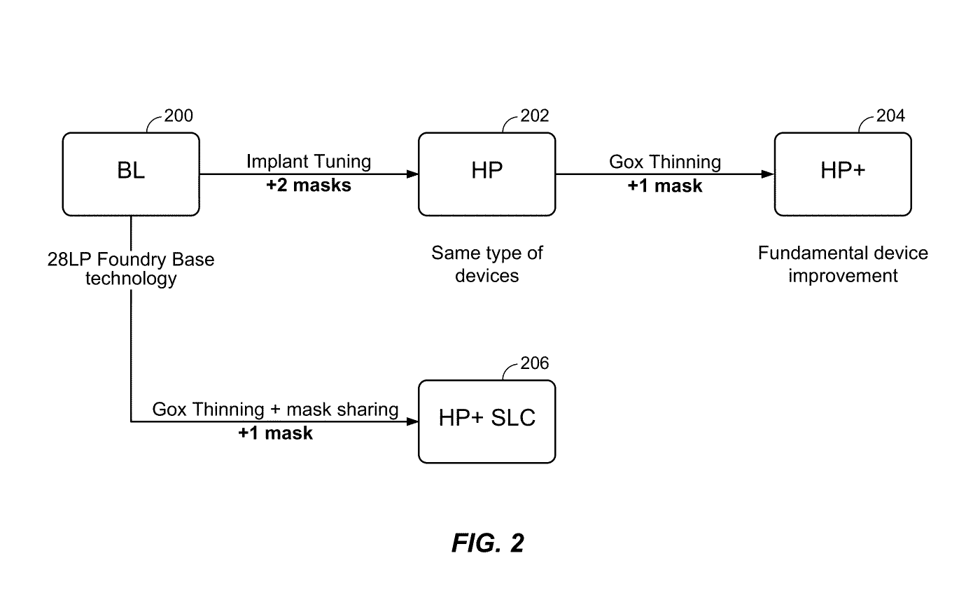

As designs in the baseline technology shown in FIG. 1 are improved, additional processing steps are implemented in the manufacturing process for the devices. As shown in FIG. 2, in many foundry base technologies, such as a 28 nm low power (28LP) technology, the first step after the baseline technology 200 to achieve high performance (HP) devices is to change the dopant implantation densities in some of the source/drain regions in the various devices in the integrated circuit. Such IC devices can be referred to as HP technology 202. With reference to FIG. 1, HP devices can be created by varying or changing the dopant type and densities in the source/drain regions 106, 108, 116, and 118, to change the available charge carriers in the channels 109 and/or 119. In complementary metal-oxide-semiconductor (CMOS) technologies, this changing of the dopant implantation densities and type (LDD/Halo implantation) of both the n-type dopant and the p-type dopant may be known as “implantation threshold tuning” the integrated circuit. Two additional masks can be used to change the implantation densities and type in portions of the dopant regions 106, 108, 116 and 118 within the integrated circuit.

Transistor speed and performance can further be improved by thinning the gate oxide layer 110 and/or 120 in CMOS circuitry, allowing for lower threshold voltages (also known as “turn-on” voltages) within the devices in the integrated circuit. Again, referring to FIG. 1, as the gate oxide layers 110 and 120 are thinned, the same voltage applied to the gate electrodes 112 and 122 will generate a larger electric field in the channels 109 and 119. The larger electric field creates a lower threshold voltage to create channel conduction. Such devices are considered “high performance plus” (HP+) devices and are represented by block 204, because they often provide fundamental device improvements, such as higher speed devices, within the integrated circuit. This approach again uses an additional mask to thin the gate oxide layers 110 and 120 for those areas of the circuit that may have higher speed or lower threshold voltages.

Thus, although performance (e.g., higher speed, lower power) for the devices is improved, the manufacturing costs are increased. The increased manufacturing costs are due to the two additional semiconductor masks that are used for the HP devices. In addition, three additional masks are used for the HP+ devices.

As circuit designs become more complex, multiple threshold voltages (e.g., a standard voltage threshold (SVT) as the first threshold device, a low voltage threshold (LVT) as the second threshold device, an ultra-standard voltage threshold (μSVT) as the third threshold device, an ultra-low voltage threshold (μLVT) as the fourth threshold device, etc.) become a standard part of the integrated circuit design and fabrication. These threshold voltages are controlled by changing the dopant densities and type (LDD/Halo implantation) in the source/drain regions or the gate oxide thickness (or by adding “halo”/low-dopant drain (LDD) masks, which effectively shorten the channel length, or triple gate mask). As such, both dopant implant tuning and gate oxide thinning in CMOS has become important to allow for the multiple voltage thresholds in these designs.

One approach to reduce the cost for such circuits is mask sharing. Mask sharing uses one of the original implant masks to create the various threshold voltages mask and one additional mask for gate oxide thinning. Such an approach is known as a high performance plus simple low cost (HP+SLC) approach, shown in an SLC block 206. Nevertheless, these devices are not “tunable” in that the NMOS and PMOS drive current ratio (N/P ratio) for ultra threshold devices are fixed.

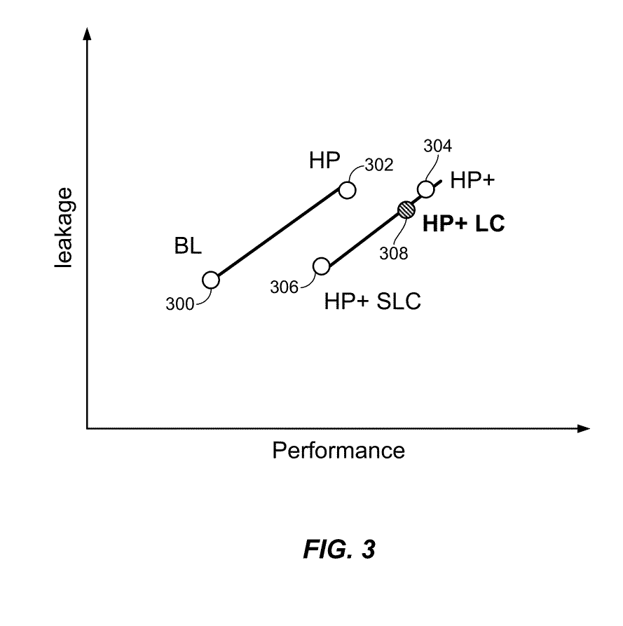

FIG. 3 illustrates the technology regression for HP+SLC devices. Baseline (BL) technology devices show frequency operation at point 300, HP device at point 302, HP+ device operating at point 304, HP+SLC devices operating at point 306, and HP+LC device operating at point 308. BL devices at point 300 and HP devices at point 302 are operating in different trend curves than HP+SLC, HP+LC, and HP+ devices. The HP+SLC approach significantly degrades performance of the circuit.

The HP+SLC approach saves manufacturing costs on the integrated circuit because the dopant tuning masks for both n-type dopants and p-type dopants are removed from the manufacturing flow. However, because additional dopant tuning masks are no longer provided in this approach to circuit manufacturing, there is no longer any flexibility to tune any ultra-low-threshold devices within the circuit and thus to increase performance. This may shift the overall performance to a slower speed than the baseline technology, which is undesirable.

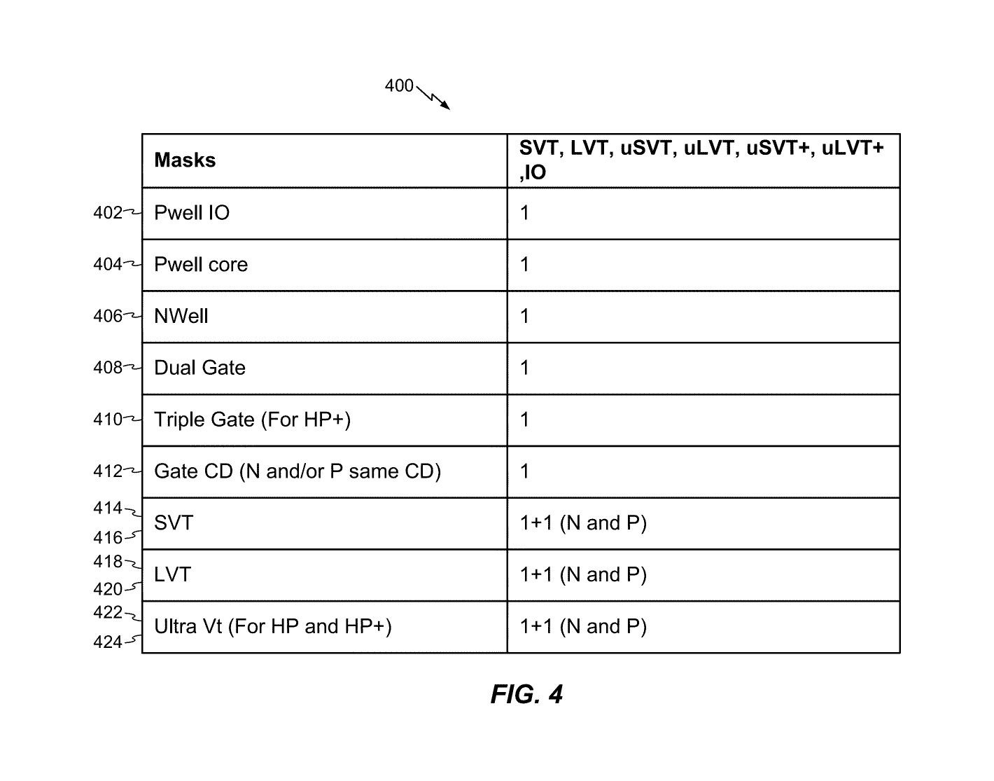

Multiple threshold voltage (Vt) CMOS technology uses different threshold voltage low dopant drain (LDD)/Halo implant masks to create the different threshold voltage transistors. For example, for multiple threshold voltage transistors in CMOS, 12 masks are used, as shown in FIG. 4.

### Mask Functions

The chart 400 shows that in the related art, for the seven different types of devices (e.g., a standard voltage threshold (SVT) as the first threshold, a low voltage threshold (LVT) as the second threshold, an ultra-standard voltage threshold (μSVT) as the third threshold, an ultra-low voltage threshold (μLVT) as the fourth threshold, an ultra-standard voltage threshold (μSVT+) as the fifth threshold, an ultra-low voltage threshold (μLVT+) as the sixth threshold) and input/output (I/O) devices in both NMOS and PMOS, fourteen different device types in total are created.

For the p-well I/O devices, one p-well I/O mask 402 is used. For the p-well core devices, one p-well core mask 404 is used. For the n-wells in both types of devices, one n-well mask 406 is used. For the dual gate devices, one dual gate mask 408 is used. For the triple gate devices, where there are three gate oxide thicknesses (HP+), one triple gate mask 410 is used. For the gate critical dimension (CD), where both n-type and p-type devices have the same CD, one gate CD mask 412 is used. The gate CD mask 412 may be used to mask polysilicon or gate layers, and, as such, may also be referred to as a “poly mask 412.”

For standard voltage threshold (SVT) devices, two masks are used; one n-SVT mask 414 for n-type devices and one p-SVT mask 416 for p-type devices with a dual gate mask 408. For low voltage threshold (LVT) devices, two masks are used: one n-LVT mask 418 for n-type devices and one p-LVT mask 420 for p-type devices with the dual gate mask 408. For ultra threshold (e.g., μSVT and μLVT) devices, with two turning on threshold voltages mask SVT and LVT and triple gate mask 410, five masks are used: one n-ultra-low threshold voltage (e.g., μSVT+, μLVT+) mask 422 for n-type devices and one p-ultra-low threshold voltage mask 424 for p-type devices with a triple gate mask 410. As such twelve masks 402-424 create the fourteen different types of devices in multiple threshold voltage CMOS process technology.

Within a multiple threshold voltage CMOS circuit, the n-well mask 406 may create a standard dopant density, which results in a standard threshold (turn-on) voltage, for the PMOS core devices and a standard threshold (turn-on) voltage in the PMOS I/O devices. Similarly, the p-well core mask 404 creates the standard threshold (turn-on) voltage in the NMOS core devices. The p-well I/O mask 402 may be used to tune the voltage in the NMOS I/O devices to a lower threshold voltage.

The dual gate mask 408 may create core devices for the standard voltage threshold (SVT) devices, the low voltage threshold (LVT) devices in both the PMOS and NMOS devices within the circuit. The triple gate mask 410 may create the ultra-low-voltage threshold (μSVT and μLVT) devices and the ultra-low threshold voltage devices for the uSVT+ and uLVT+ devices in both the PMOS and NMOS devices within the circuit. The gate CD mask 412 may be used to create the gate dimension (via the sizing of the gate critical dimension) in all of the devices.

The n-SVT mask 414 is used to increase the threshold voltage in NMOS SVT, uSVT, and uSVT+ devices. The p-SVT mask 416 is used to increase the threshold voltage in PMOS SVT, uSVT, and uSVT+ devices. The n-LVT mask 418 is used to decrease the threshold voltage in NMOS LVT and uLVT devices as well as NMOS SVT and uSVT devices. The p-LVT mask 420 is used to decrease the threshold voltage in PMOS LVT and uLVT devices and SVT and uSVT devices. The n-ultra-low threshold voltage mask 422 is used to greatly reduce the threshold voltage for n-type devices (e.g., uSVT+, uLVT+). The p-ultra-low threshold voltage mask 424 is used to greatly reduce the threshold voltage for p-type devices (e.g., uSVT+, uLVT+).

For integrated circuits with multiple threshold voltages that are integrated with static random access memory (SRAM) circuitry, additional masks, often referred to as a SRAM n-halo/low doped drain (LDD) mask and a SRAM p-halo/LDD mask, may also be included in the processing of the integrated circuit. The SRAM n-halo/LDD mask may tune the SRAM threshold on voltages for pull down (PD) and pass gate (PG) transistors and the SRAM p-halo/LDD mask may tune the threshold voltage for pull-up (PU) transistors. With SRAM circuitry included, a total of fourteen device masks may be used.

### Combined Mask Function Examples

Instead of sharing both ultra-low-threshold NMOS and PMOS masks with baseline implant masks, the present disclosure shares only one of the ultra-low-voltage threshold NMOS or PMOS implantation masks. Thus, the drive current in one of the MOS devices is fully tunable, which keeps the drive current ratio (the N/P ratio) tunable for uSVT, uLVT, uSVT+, uLVT+ separately. By adding the triple gate mask, uSVT, uLVT, uSVT+, and uLVT+ devices can be created. Compared to HP devices, the present disclosure uses one fewer mask, and the present disclosure has improved performance over HP devices

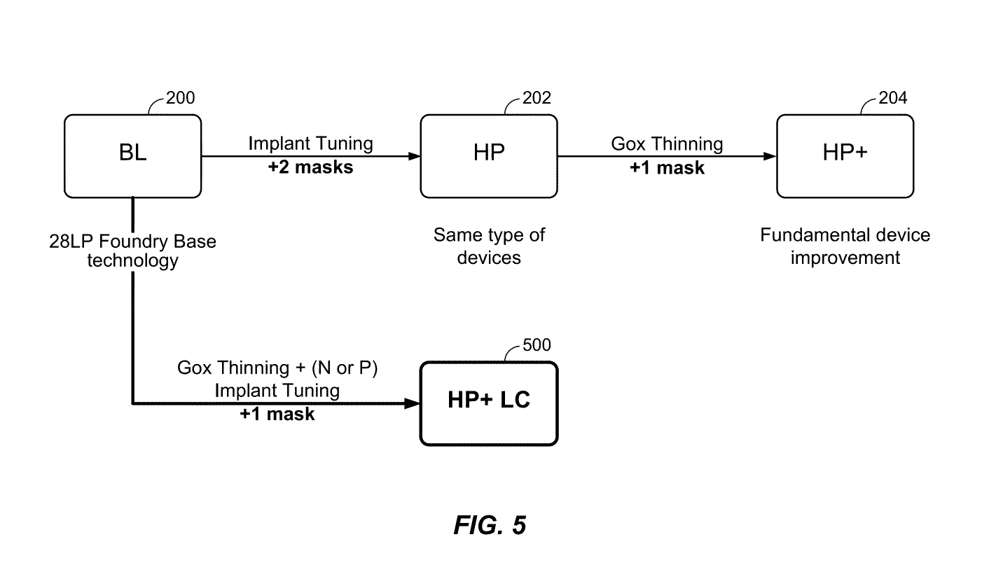

Compared to the HP+SLC flow in FIG. 2, the proposed method flow of FIG. 5 uses the same number of masks in block 500 as in the HP+SLC block 206 of FIG. 2, and still has improved performance with devices for both leakage current and operating frequency. Further, the devices made in accordance with aspects of the present disclosure can be tuned for particular product specifications, which extend the use of low cost products. For example, the threshold (turn-on) voltages can be tuned separately in uSVT, uLVT, uSVT+, and uLVT+ devices made in accordance with an aspect of the present disclosure, whereas HP+SLC devices cannot. Such advantages are not available in HP+SLC technologies.

The present disclosure combines the P-core and P-I/O (input/output) masks for the wells, and uses a gate critical dimension (CD) bias at the various threshold voltages and drive currents, as desired, to tune the drive current and the N/P ratio. The critical dimension (CD) refers to the channel length. The present disclosure uses a single ultra-low voltage threshold mask, either NMOS or PMOS, to further tune the N/P ratio and turn-on voltage/current to maintain performance and yield.

In an aspect of the present disclosure, ten device masks generate twelve types of devices (N and P channel devices of SVT, LVT, μSVT, μLVT, μSVT+, μLVT+, etc.). These ten device masks enable drive current (Ion) and turn-off current (Ioff) for different type devices for low power processes. The table below illustrates the types of devices and the corresponding gate oxides.

| Mask | BL | HP | HP+ | HP + SLC | HP + LC |
|---|---|---|---|---|---|
| NMOS | SVT, LVT | SVT, LVT, | SVT, LVT, | SVT, LVT, | SVT, LVT, |
| | | uSVT, uLVT | uSVT, uLVT, | uSVT+, uLVT+ | uSVT, uLVT, |
| | | | uSVT+, uLVT+ | | uSVT+, uLVT+ |
| PMOS | SVT, LVT | SVT, LVT, | SVT, LVT, | SVT, LVT, | SVT, LVT, |
| | | uSVT, uLVT | uSVT, uLVT, | uSVT+, uLVT+ | uSVT, uLVT, |
| | | | uSVT+, uLVT+ | | uSVT+, uLVT+ |
| Gate | Dual | Dual | Triple | Triple | Triple |
| oxide | | | | | |

If the P-μLVT+ and P-uLVT/P-uSVT devices are more dominant in terms of speed and leakage current (Iddq) than the n-channel devices of the same technology level, the p ultra Vt and the shared n ultra Vt masks can be used to change the drive current N/P ratio. Changing the drive current ratio allows the n-type devices to achieve comparable speeds with the tunable p-type devices. The gate CD mask may also be used to tune the n-type and p-type devices. Similarly, if the n-type devices dominate in terms of speed, the ultra-threshold mask and the shared p ultra Vt mask can change the drive current in the n-type devices.

Another aspect of the present disclosure uses two fewer masks than the baseline process. The baseline process may use a total of twelve device masks. This aspect of the present disclosure generates ten different kinds of devices (N and P types of SVT, LVT, μSVT, μLVT, μSVT+, μLVT+, SRAM, etc.), and still maintains drive current (Ion) and turn-off current (Ioff) for low power device applications. The additional mask improves or even optimizes the process window, which may be performed by using the combined LVT and ultra-low Vt mask.

Another aspect of the present disclosure may employ ten total device masks to generate ten different types of devices (N and P of SVT, LVT, μSVT, μLVT, μSVT+, μLVT+, SRAM, etc.) and still maintain drive current (Ion) and turn-off current (Ioff) for low power device applications.

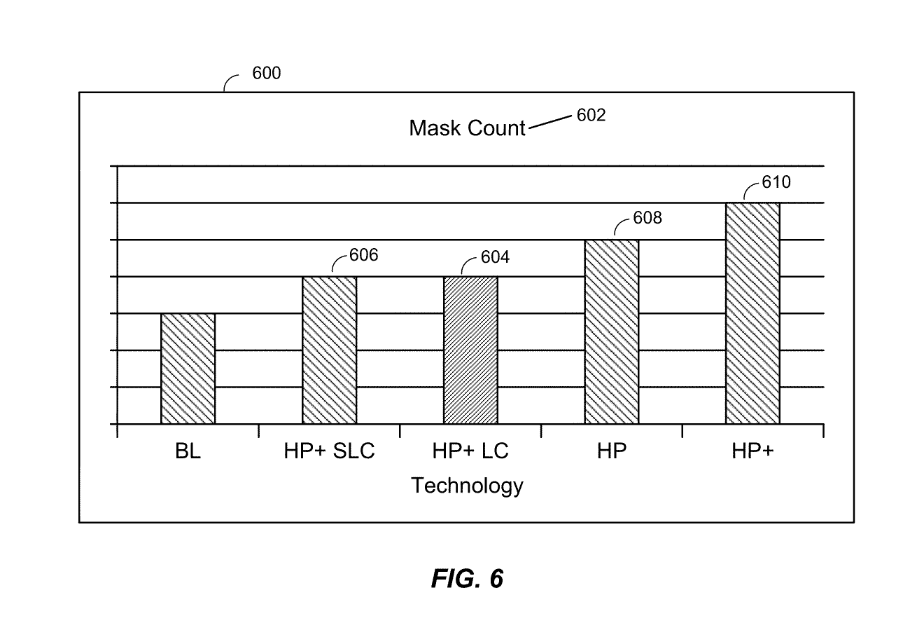

FIG. 6 illustrates a mask count for technology improvement in accordance with an aspect of the present disclosure. The mask count for the present disclosure is equivalent to that of HP+SLC technology and has higher performance.

Graph 600 illustrates a mask count 602 for several different technology approaches. The mask count 604 in accordance with an aspect of the present disclosure is shown as equivalent to a mask count 606 for the HP+SLC technology, and less than a mask count 608 for HP technology and a mask count 610 for HP+ technology approaches.

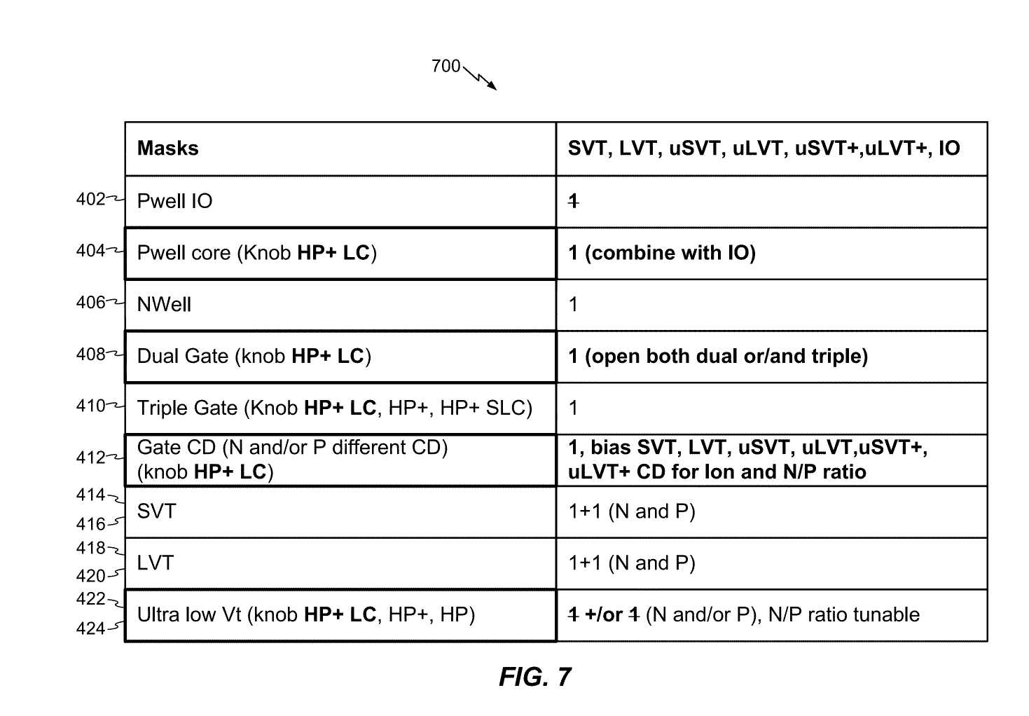

FIG. 7 illustrates a mask chart 700 for high performance plus low cost devices in accordance with an aspect of the present disclosure. The mask chart 700 illustrates the use of masks 402-424 in this aspect of the present disclosure. In this example, the p-well I/O mask 402 is combined with the p-well core mask 404 for the same functions on the integrated circuit, and the p-well I/O mask 402 is not used. The p-well core mask 404 is used as a tuning mask (e.g., a “knob”) to control the threshold voltages in both the core and I/O devices.

The n-well mask 406 and the dual gate mask 408 are still utilized, but these masks may be used for tuning the devices within the integrated circuit, according to an aspect of the present disclosure. Both the dual gate mask 408 and the triple gate mask 410 are used to tune the HP+LC circuits, whereas the triple gate mask 410 is used as a tuning mask for HP+LC, HP+ and HP+SLC circuits.

One of the n-ultra-low threshold voltage mask 422 and the p-ultra-low threshold voltage mask 424 may be eliminated from the process. A mask can be eliminated because only one of the n-ultra-low threshold voltage mask 422 or the p-ultra-low threshold voltage mask 424 is used to tune the drive current and N/P ratio in the circuitry, and thus is used as a knob for HP+LC circuits, as it is with HP+ and HP circuits. The gate CD mask 412 is used as a control mask to control the drive current (Ion) and drive current ratio (N/P ratio), as well as a biasing mask for the multiple threshold voltages. As such, the gate CD mask 412 is used as a tuning mask, or knob, for HP+LC circuits in an aspect of the present disclosure. Further, in an aspect of the present disclosure, only ten masks are used to create the fourteen different types of devices as described with respect to FIG. 6, rather than twelve masks in the related art. The p-well I/O mask 402 and one of the n-ultra-low threshold voltage masks 422 or the p-ultra-low threshold voltage mask 424 are eliminated from the process flow, thereby reducing costs and increasing processing throughput.

### P-type Device Dominant Example

Certain mask functions may be combined in an aspect of the present disclosure. The p-well I/O mask 402 function may no longer be used, because the p-well core mask 404 is now designed to perform this function during the processing of the CMOS integrated circuit of the present disclosure. The p-well core mask 404 may be used for n-type I/O devices. Different critical dimensions may be integrated on the same gate CD mask 412. Some functions of the n-ultra-low threshold voltage mask 422 may no longer be used because they may be integrated in the N-LVT mask 418. Similarly, the functions of the p-ultra-low threshold voltage mask 424 that are not used may be integrated in the P-LVT mask 420.

In another aspect of the present disclosure, the p-well core mask 404 may not be used, and the p-well I/O mask 402 may be used to create the threshold voltages in both the NMOS core and the NMOS I/O devices. This lower threshold in the core devices may be compensated for by using the gate CD mask 412 to create various gate CDs for the NMOS core devices. Similarly, the n-ultra-low threshold voltage mask 422 may not be used because the functions may be integrated with the n-LVT mask 418.

If the p-type devices dominate a faster circuit speed and a lower circuit leakage current (Iddq), then this aspect of the present disclosure may be used, which eliminates the p-well core mask 404 and the n-ultra-low threshold voltage mask 422. The triple gate mask 410 may be used to make/tune the ultra-low threshold type devices. The p-ultra-low threshold voltage mask 424 may be used to generate the p-type ultra-low threshold voltage devices. The gate CD mask 412 may be used to tune the n-type devices. The p-type device thresholds may be tunable by the p-SVT mask 416, the p-LVT mask 420, and the p-ultra-low threshold voltage mask 424. The triple gate mask 410 and the gate CD mask 412 may be used as tuning knobs to fix n-type device drive current to improve the process window. This aspect of the present disclosure saves two masks over the related art.

When SRAM circuitry is included in a multiple-threshold voltage circuit, the p-well I/O mask 402 may also be used to create the threshold voltages in the NMOS SRAM devices if sharing a PMOS SRAM LDD/Halo mask with one of device implantation masks. The changes in threshold voltage in the PMOS SRAM devices may be compensated for by using the gate CD mask 412 to create additional changes in the gate CDs for the PMOS SRAM devices. This aspect of the present disclosure may also eliminate the use of the SRAM p-halo/LDD mask by integrating the SRAM p-halo/LDD mask functions into the p-ultra-low threshold voltage mask 424. This aspect of the present disclosure saves three masks over the related art.

### N-type Device Dominant Example

In another aspect of the present disclosure, the p-well core mask 404 may not be used, and the p-well I/O mask 402 may be used to create the threshold voltages in both the NMOS core and the NMOS I/O devices. This lower threshold in the core devices may be compensated for by using the gate CD mask 412 to create various gate CDs for the NMOS devices and may also create various gate CDs for the PMOS devices to get devices on target. The p-LVT mask 420 may also be used to create different voltage thresholds in the PMOS devices. Rather than eliminating the n-ultra-low threshold voltage mask 422, the p-ultra-low threshold voltage mask 424 may not be used, because these functions may be integrated with the p-LVT mask 420.

If the n-type devices dominate a faster circuit speed and a lower circuit leakage current (Iddq), then this aspect of the present disclosure may be used, which eliminates the p-well core mask 404 and the p-ultra-low threshold voltage mask 424. The n-ultra-low threshold voltage mask 422 may be used to make/tune the n-type ultra-low threshold devices, and also may be used to tune the N/P ratio. The n-ultra-low threshold voltage mask 422 may be used to generate the n-type ultra-low threshold voltage devices. The gate CD mask 412 may be used to tune the p-type devices. The p-type device thresholds may be fixed using the p-SVT mask 416, and the p-LVT mask 420. The p-ultra-low threshold voltage mask 424, and the p-SVT mask 416 and the p-LVT mask 420, may be used as tuning knobs to tune the N/P ratio separately, and to improve the process window. This aspect of the present disclosure saves two masks over the related art.

When SRAM circuitry is included in a multiple-threshold voltage circuit, the p-well I/O mask 402 may also be used to create the threshold voltages in the NMOS SRAM devices. If sharing an NMOS SRAM LDD/Halo mask with one of device implantation, the changes in threshold voltage in the NMOS SRAM devices may be compensated for by using the gate CD mask 412 to create additional changes in the gate CDs for the SRAM NMOS devices. This aspect of the present disclosure may also eliminate the use of the SRAM n-halo/LDD mask by integrating the SRAM n-halo/LDD mask functions into the n-ultra-low threshold voltage mask 422. This aspect of the present disclosure saves three masks over the related art.

### Flow Diagram

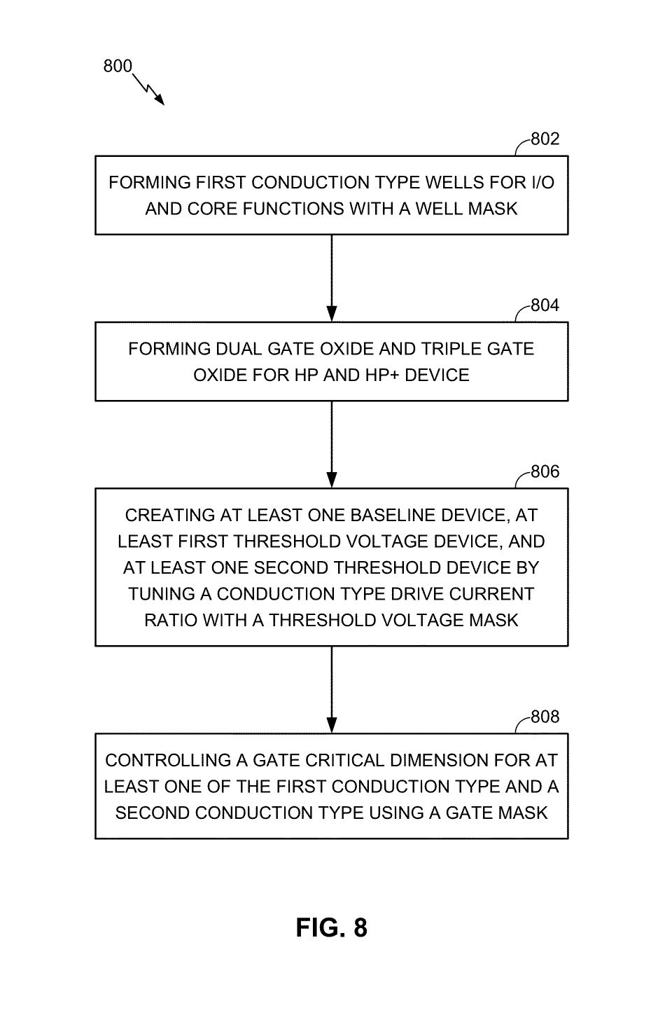

FIG. 8 is a flow diagram illustrating a process 800 in accordance with an aspect of the present disclosure. The process 800 is a method of fabricating a CMOS device that includes I/O and core in this aspect of the disclosure. At block 802, first conduction type wells for I/O and core functions are formed with a well mask. At block 804, a dual gate oxide and a triple gate oxide are formed for ultra threshold devices. At block 806, a baseline device, a first threshold voltage device and a second threshold device are created. These devices may be created by tuning a drive current ratio with a threshold voltage mask. Block 808 illustrates controlling a gate critical dimension (CD) for the first conduction type and/or a second conduction type using a gate mask.

Thus, according to one aspect of the present disclosure, I/O and core mask functions, commonly using p-wells, are combined to share well implant dosages. Moreover, individual SVT, LVT, μSVT, μLVT, μSVT+, μLVT+ gate CD may be biased to tune device performance. Furthermore, the ultra-threshold mask can be combined with the LVT mask and they can share the LDD/Halo implant dosage. These improvements can combine some SRAM device LDD/Halo implants with core Halo/LDD implants for additional mask reduction. Two or three implant masks can be eliminated, but performance is maintained and/or improved over other approaches. The threshold voltages and the device drive current N/P ratio remain tunable for circuit performance, and leakage current may also be maintained or reduced. When combining multiple threshold circuitry with SRAM circuitry, additional masks and processing steps are saved.

A configuration of the present disclosure includes a complementary metal oxide semiconductor (CMOS) device including input/output (I/O) devices and core function devices. The CMOS device is manufactured with a mask set that includes means for forming first conduction type wells for the I/O devices and the core function devices. In one aspect of the disclosure, the forming means may be the p-well core mask 404 or other means configured to perform the functions recited by the well mask means. In this configuration, the mask set also includes means for creating at least one baseline device, at least a first threshold voltage device, and at least one second threshold device by tuning a conduction type drive current ratio. In an aspect of the present disclosure, the creating means may be the p-SVT mask 416, the p-LVT mask 420, the p-ultra-low threshold voltage mask 424, or other means configured to perform the functions recited by the threshold voltage mask means. In this configuration, the mask set also includes means for controlling a gate critical dimension for at least one of the first conduction type or a second conduction type. In an aspect of the present disclosure, the controlling means may be the triple gate mask 410, the gate CD mask 412, or other means configured to perform the functions recited by the controlling means. In another aspect, the aforementioned means may be any module or any apparatus configured to perform the functions recited by the aforementioned means.

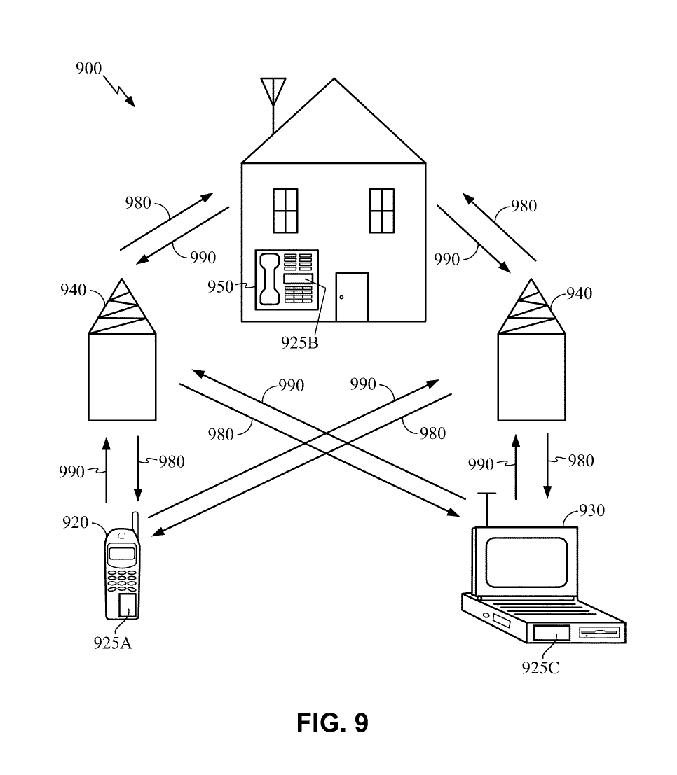

FIG. 9 is a block diagram showing an exemplary wireless communication system 900 in which an aspect of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925C, and 925B that include the disclosed CMOS devices. It will be recognized that other devices may also include the disclosed CMOS devices, such as the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the disclosed CMOS devices.

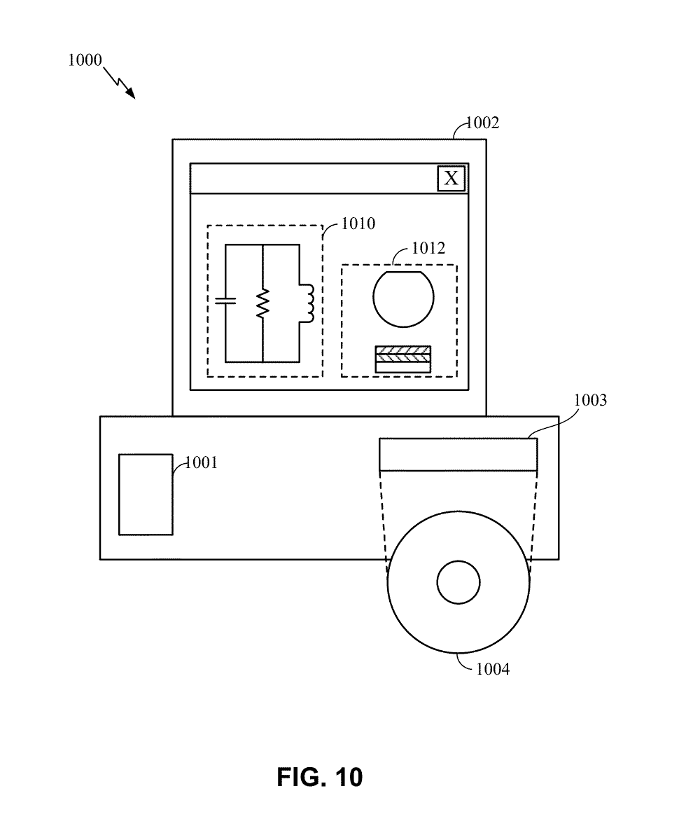

FIG. 10 is a block diagram illustrating a design workstation used for circuit, layout, and logic design of a semiconductor component, such as the CMOS devices disclosed above. A design workstation 1000 includes a hard disk 1001 containing operating system software, support files, and design software such as Cadence or OrCAD. The design workstation 1000 also includes a display 1002 to facilitate design of a circuit 1010 or a semiconductor component 1012 such as a CMOS device. A storage medium 1004 is provided for tangibly storing the design of the circuit 1010 or the semiconductor component 1012. The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. A computer-readable medium may include, by way of example, memory such as a magnetic storage device (e.g., hard disk, floppy disk, magnetic strip), an optical disk (e.g., compact disc (CD), digital versatile disc (DVD)), a smart card, a flash memory device (e.g., card, stick, key drive), random access memory (RAM), read only memory (ROM), programmable ROM (PROM), erasable PROM (EPROM), electrically erasable PROM (EEPROM), a register, or a removable disk. Although memory is shown separate from the processors in the various aspects presented throughout this disclosure, the memory may be internal to the processors (e.g., cache or register).

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A method for fabricating a complementary metal oxide semiconductor (CMOS) device including input/output (I/O) devices and core function devices, comprising:
forming first conduction type wells for the I/O devices and the core function devices with a well mask;
creating at least one baseline device of a first conduction type, at least one first threshold voltage device of the first conduction type, and at least one second threshold voltage device of the first conduction type by tuning a conduction type drive current ratio with a threshold voltage mask; and
controlling a gate critical dimension for at least one of the first conduction type devices or at least one second conduction type device using a gate mask.

2. The method of claim 1, in which the first threshold voltage device is a dual gate device.

3. The method of claim 1, in which the second threshold voltage device is a triple gate device.

4. The method of claim 1, in which the gate mask enables performance tuning for a predetermined device characteristic.

5. The method of claim 4, in which the gate mask enables the performance tuning of the predetermined device characteristic for at least one of the first conduction type devices and at least one of the second conduction type devices.

6. The method of claim 1, further comprising combining at least one core halo mask with a memory implant mask.

7. The method of claim 1, further comprising integrating the CMOS device into a mobile phone, a set top box, a music player, a video player, an entertainment unit, a navigation device, a computer, a hand-held personal communication systems (PCS) unit, a portable data unit and/or a fixed location data unit.

8. A complementary metal oxide semiconductor (CMOS) device including input/output (I/O) devices and core function devices, the CMOS device manufactured with a mask set, comprising:
means for forming first conduction type wells for the I/O devices and the core function devices;
means for creating at least one baseline device, at least a first threshold voltage device, and at least one second threshold voltage device by tuning a conduction type drive current ratio; and
means for controlling a gate critical dimension for at least one of a first conduction type or a second conduction type.

9. The CMOS device of claim 8, in which the first threshold voltage device is a dual gate device.

10. The CMOS device of claim 8, in which the second threshold voltage device is a triple gate device.

11. The CMOS device of claim 8, in which the controlling means tunes performance for a predetermined device characteristic.

12. The CMOS device of claim 11, in which the controlling means tunes the predetermined device characteristic for the first conduction type and the second conduction type.

13. The CMOS device of claim 8, further comprising means for controlling an implant density in the core function devices and in a memory device.

14. The CMOS device of claim 8, integrated into a mobile phone, a set top box, a music player, a video player, an entertainment unit, a navigation device, a computer, a hand-held personal communication systems (PCS) unit, a portable data unit and/or a fixed location data unit.

15. A complementary metal oxide semiconductor (CMOS) device including input/output (I/O) devices and core function devices, the CMOS device manufactured with a mask set, comprising:
a well mask that forms first conduction type wells for the I/O devices and the core function devices;
a threshold voltage mask that creates at least one baseline device, at least a first threshold voltage device, and at least one second threshold voltage device by tuning a conduction type drive current ratio; and
a gate mask that controls a gate critical dimension for at least one of the first conduction type or a second conduction type.

16. The CMOS device of claim 15, in which the first threshold device is a dual gate device.

17. The CMOS device of claim 15, in which the second threshold voltage device is a triple gate device.

18. The CMOS device of claim 15, in which the gate mask enables performance tuning of a predetermined device characteristic.

19. The CMOS device of claim 18, in which the gate mask enables the performance tuning of the predetermined device characteristic for the first conduction type and the second conduction type.

20. The CMOS device of claim 15, integrated into a mobile phone, a set top box, a music player, a video player, an entertainment unit, a navigation device, a computer, a hand-held personal communication systems (PCS) unit, a portable data unit and/or a fixed location data unit.
